(19) United States
(12) Patent Application Publication
(10) Pub. No.: US 2005/0153248 A1
(43) Pub. Date: Jul. 14, 2005

(54) Method for fabricating a molding core

(75) Inventors: Tai-Cherng Yu, Tu-Cheng (TW); Charles Leu, Fremont, CA (US); Ga-Lane Chen, Fremont, CA (US)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 10/997,365

(22) Filed: Nov. 23, 2004

(30) Foreign Application Priority Data
Jan. 13, 2004 (TW) 93100744

(51) Int. Cl. G03F 7/00

(52) U.S. Cl. 430/322; 430/320

(57) ABSTRACT

A method for fabricating a molding core includes: (a) providing a metal substrate; (b) coating a photo-resist layer on the metal substrate; and (c) exposing and developing the photo-resist layer using a photo-mask having a predetermined pattern to form a photo-resist pattern. The substrate and the photo-resist pattern constitute the molding core. The method does not require an etching step to etch a necessary pattern on the substrate. The photo-resist pattern is used as the pattern of the molding core. Therefore the method is simple, productivity is increased, and costs are reduced.

### BACKGROUND OF THE INVENTION

1. Field of the Invention

The present invention relates to a method for fabricating a molding core used in a hot-embossing process, the hot-embossing process being employed for making products such as light guide plates for liquid crystal displays (LCDs).

2. Description of the Prior Art

At present, molding cores are widely utilized in many kinds of production processes, including the manufacturing of light guide plates for LCDs. Conventional methods for fabricating molding cores require a long production period, typically about one month. Although the methods for fabricating molding cores are gradually being improved, they are still very protracted. Fabricating a molding core significantly extends the overall time needed to manufacture the associated product, such as an LCD.

Referring to FIG. 5, a conventional method for fabricating a molding core includes the following steps: (1) providing a metal substrate (step 101); (2) coating a photo-resist layer on the substrate (step 102); (3) exposing and developing the photo-resist layer (step 103); (4) etching the substrate to form a pattern (step 104); and (5) stripping the photo-resist layer to form a molding core having the pattern (step 105).

The above method requires an etching step after the photo-resist layer is developed, in order to form the necessary pattern on the substrate. This makes the process unduly complex. Consequently, productivity is relatively low, and costs are relatively high.

It is desired to provide an improved method for fabricating a molding core that overcomes the above-described problems.

### SUMMARY OF THE INVENTION

Accordingly, an object of the present invention is to provide a method for fabricating a molding core, the method being simple and yielding high productivity.

In order to achieve the above-mentioned object, a method of the present invention for fabricating a molding core comprises the following steps: (a) providing a metal substrate; (b) coating a photo-resist layer on the metal substrate; and (c) exposing and developing the photo-resist layer using a photo-mask having a predetermined pattern to form a photo-resist pattern. The substrate and the photo-resist pattern constitute the molding core.

In summary, the method of the present invention does not require an etching step to etch a necessary pattern on the substrate. The photo-resist pattern is used as the pattern of the molding core. Therefore, the method is simple, productivity is increased, and costs are reduced.

Other objects, advantages and novel features of the present invention will be apparent from the following detailed description of preferred embodiments thereof with reference to the attached drawings, in which:

### BRIEF DESCRIPTION OF THE DRAWINGS

FIG. 1 is a flow chart of a method for fabricating a molding core according to the present invention;

FIG. 2 is a schematic, cross-sectional view of a substrate having a photo-resist layer coated thereon, according to the method of the present invention;

FIG. 3 is similar to FIG. 2, but also showing a photo-mask used to expose the photo-resist layer;

FIG. 4 shows the substrate of FIG. 3 after a developing step has been completed, whereby a photo-resist pattern is formed on the substrate; and

FIG. 5 is a flow chart of a conventional method for fabricating a molding core.

### DETAILED DESCRIPTION OF THE INVENTION

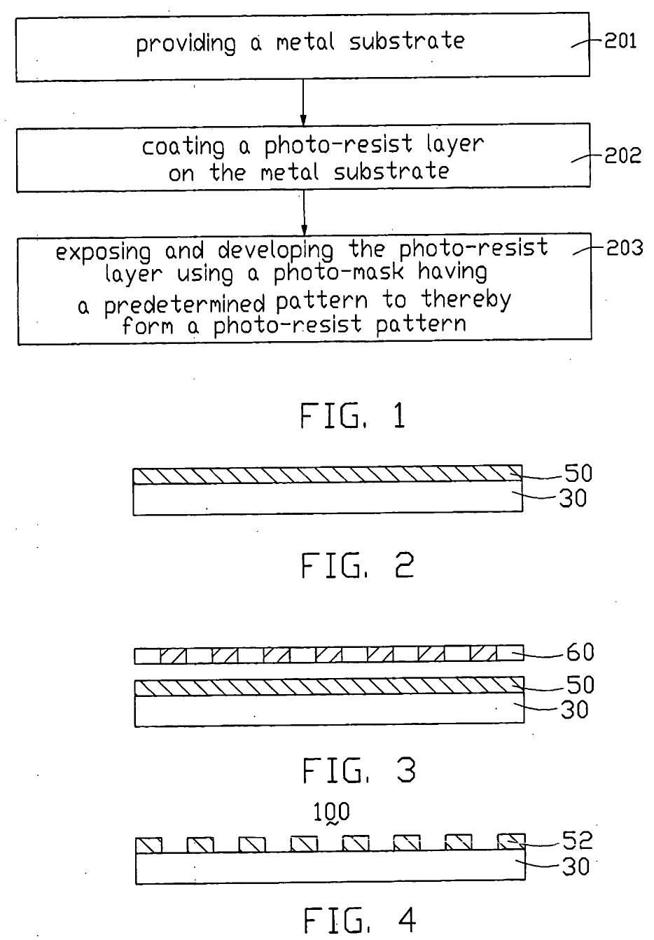

Referring FIG. 1, a method for fabricating a molding core of the present invention includes three steps: (a) providing a metal substrate (step 201); (b) coating a photo-resist layer on the metal substrate (step 202); and (c) exposing and developing the photo-resist layer using a photo-mask having a predetermined pattern to thereby form a photo-resist pattern (step 203). The substrate and the photo-resist pattern constitute the fabricated molding core.

Referring to FIG. 2, in the first step, a substrate 30 is provided. The substrate 30 is made of a metal having high rigidity, for example nickel. The substrate 30 is baked in a vacuum or in a nitrogen environment at a temperature between 100° C. and 120° C. for 4˜6 minutes, in order to dehydrate the substrate 30. After that, a photo-resist layer 50 is coated on the substrate 30 by a spin-coating method or a spray-coating method. The photo-resist layer 50 is an organic, negative photo-resist. Then, the substrate 30 having the photo-resist layer 50 is baked at a temperature between 90° C. and 100° C. for 20˜30 minutes.

Referring to FIG. 3, in the second step, the photo-resist layer 50 is exposed and developed. Ultraviolet (UV) radiation is emitted through a photo-mask onto the photo-resist layer 50, the photo-mask having a predetermined pattern. Exposed parts of the photo-resist layer 50 receive the UV radiation, whereby the exposed parts become resistant to being dissolved in a developer.

After exposure, a baking step is performed again. The substrate 30 having the photo-resist pattern 52 is baked at a temperature between 100° C. and 120° C. for 20˜30 minutes, in order to make the exposed parts of the photo-resist layer 50 further resistant to being dissolved.

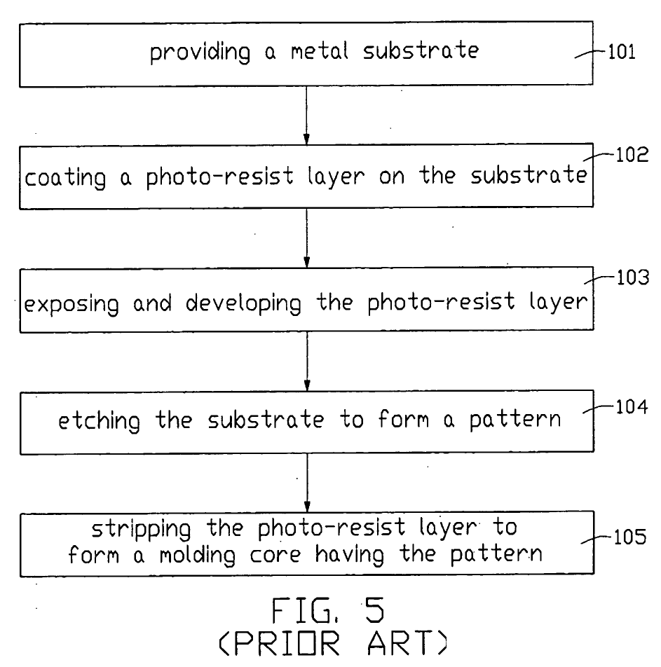

Referring to FIG. 4, a developer which can dissolve the negative photo-resist is sprayed onto the photo-resist layer 50. The substrate 30 is maintained for 30˜60 seconds in order that the unexposed parts of the photo-resist layer 50 are fully dissolved. The exposed parts of the photo-resist layer 50 remain, and cooperatively define a photo-resist pattern 52. The photo-resist pattern 52 and the substrate 30 constitute a molding core 100 of the present invention.

The present invention may have other embodiments as follows. The substrate 30 can be made of copper. The photo-resist layer 50 can be an organic, positive photo-resist. If an organic, positive photo-resist is used, a developer that can dissolve a positive photo-resist should also be used. In such case, the exposed parts of the photo-resist layer 50 are dissolved by the developer.

In summary, the method of the present invention does not require an etching step to etch a necessary pattern on the substrate 30. The photo-resist pattern 52 is used as the pattern of the molding core 100. The method is simple, productivity is increased, and costs are reduced.

It is to be understood that even though numerous characteristics and advantages of the present invention have been set out in the foregoing description, together with details of the steps and function of the invention, the disclosure is illustrative only, and changes may be made in detail, especially in matters of arrangement of steps within the principles of the invention to the full extent indicated by the broad general meaning of the terms in which the appended claims are expressed.

1. A method for fabricating a molding core, comprising:
(a) providing a metal substrate;
(b) coating a photo-resist layer on the substrate; and
(c) exposing and developing the photo-resist layer using a photo-mask having a predetermined pattern to form a photo-resist pattern, the substrate and the photo-resist pattern constituting the molding core.

2. The method for fabricating a molding core as recited in claim 1, wherein the substrate is made of nickel.

3. The method for fabricating a molding core as recited in claim 1, wherein the substrate is made of copper.

4. The method for fabricating a molding core as recited in claim 1, wherein step (b) comprises baking the substrate in a vacuum or in a nitrogen environment at a temperature between 100° C. and 120° C. for 4˜6 minutes to dehydrate the substrate, prior to coating the photo-resist layer on the substrate.

5. The method for fabricating a molding core as recited in claim 1, wherein the photo-resist layer is spin-coated on the substrate.

6. The method for fabricating a molding core as recited in claim 1, wherein the photo-resist layer is spray-coated on the substrate.

7. The method for fabricating a molding core as recited in claim 1, wherein the photo-resist layer is an organic, negative photo-resist.

8. The method for fabricating a molding core as recited in claim 1, wherein the photo-resist layer is an organic, positive photo-resist.

9. The method for fabricating a molding core as recited in claim 1, further comprising the step of baking the substrate having the photo-resist layer coated thereon at a temperature between 90° C. and 100° C. for 20˜30 minutes.

10. A method for fabricating a mold, comprising:
preparing a substrate;
forming a photo-resist layer on said substrate; and
treating said photo-resist layer so as to form a photo-resist pattern on said substrate so as to constitute said mold.

11. The method as recited in claim 10, wherein said substrate is made of metal.

12. The method as recited in claim 10, wherein said substrate photo-resist layer is exposed to Ultraviolet (UV) radiation and then developed to form said photo-resist pattern in said treating step.

13. The method as recited in claim 10, wherein said photo-resist layer is an organic negative photo-resist layer.

14. A mold for used in a hot-embossing process, comprising:
a substrate; and
a photo-resist pattern formed on said substrate and used to result in a desired complementary pattern on a final product of said hot-embossing process to said photo-resist pattern.

15. The mold as recited in claim 14, wherein said substrate is made of metal.

16. The mold as recited in claim 14, wherein said photo-resist pattern is formed from a treated organic negative photo-resist layer.
